(19) United States
(12) Patent Application Publication
(10) Pub. No.: US 2020/0083411 A1
(43) Pub. Date: Mar. 12, 2020

(54) MANUFACTURING METHOD OF COLOR CONVERSION STRUCTURE FOR MICRO LED DISPLAY

(71) Applicant: BASS CO., LTD, Asan-si (KR)

(72) Inventors: Tae Ho PARK, Seoul (KR); Kwang Woo KWON, Yongin-si (KR); Young Soo PARK, Yongin-si (KR)

(73) Assignee: BASS CO., LTD, Asan-si (KR)

(21) Appl. No.: 16/682,277

(22) Filed: Nov. 13, 2019

Related U.S. Application Data
(63) Continuation of application No. PCT/KR2019/006339, filed on May 27, 2019.

(30) Foreign Application Priority Data
May 28, 2018 (KR) 10-2018-0060716

(51) Int. Cl. H01L 33/50; H01L 25/075

(52) U.S. Cl. CPC H01L 33/504; C03B 19/06; H01L 2933/0041; H01L 25/0753

(57) ABSTRACT

Disclosed herein is a method of manufacturing a color conversion structure for a micro light-emitting diode (LED) display, the method including dividing a lattice in a partition wall structure into a plurality of lattice groups, each having three adjacent lattices, injecting a first glass paste containing a first color conversion material and a glass powder into a first lattice of each of the plurality of lattice groups, and injecting a second glass paste containing a second color conversion material and a glass powder into a second lattice of each of the plurality of lattice groups.

### CROSS-REFERENCE TO RELATED APPLICATIONS

This application is a continuation of PCT/KR2019/006339 filed on May 27, 2019 which claims priority to Korean Patent Application No. 10-2018-0060716 filed on May 28, 2018, the entire contents of which are herein incorporated by reference.

### FIELD OF THE INVENTION

The present invention relates to a method of manufacturing a color conversion structure for a micro light-emitting diode (LED) display.

### BACKGROUND

A micro light-emitting diode (LED) is a very small LED having a size of 100 μm or less. The micro LED has a high contrast ratio, a fast response speed, and excellent power efficiency and has an advantage in that a breakage problem does not occur when bent due to a small size thereof. Therefore, a micro LED display using micro LEDs is getting attention as a next generation display.

In the micro LED display, one pixel should be comprised of three LED chips of red, green, and blue, and thus, each of the red, green, and blue LED chips should be sequentially assembled at predetermined positions on a substrate. However, in order to implement the micro LED display in high resolution, a large number of micro LEDs are required, for example, about 6.2 million micro LEDs (based on red (R), green (G), and blue (B) chips) are required for implementing full high definition (FHD) class resolution (1,920×1,080), and a lot of process time is required to assemble each of the large number of micro LEDs in a predetermined position.

In order to solve the above problem, a method of assembling a single color micro LED on a substrate and then converting a color of light emitted from an LED chip using a fluorescent material may be considered. In this case, an assembly time can be reduced by assembling micro LEDs through a method such as self-assembly, but a color conversion element should be additionally applied to each of the micro LEDs. In particular, in application of the color conversion element, when a material such as quantum dot (QD), which has excellent color reproducibility but vulnerable to heat and moisture, is used, there is a problem in that the color conversion element should be protected from external heat and external moisture.

As described above, in order to implement a micro LED display, there is a need for technological development which is capable of applying a color conversion element having excellent color conversion efficiency without changing a characteristic while reducing a process time.

### SUMMARY OF THE INVENTION

An objective of the present invention is to solve the above-described problems. Further, the present invention is directed to providing a method of manufacturing a color conversion structure for a micro light-emitting diode (LED) display, which is capable of reducing a process time of the micro LED display.

The present invention is also directed to providing a method of manufacturing a color conversion structure, which is capable of preventing degradation in characteristic of a fluorescent material used for color conversion of light emitted from an LED chip.

One aspect of the present invention provides a method of manufacturing a color conversion structure for a micro light-emitting diode (LED) display, which includes applying a glass paste for a partition wall, which contains a reflective material and a glass powder, onto a substrate in a form of a lattice; sintering the glass paste for a partition wall to form a partition wall structure; dividing the lattice in the partition wall structure into a plurality of lattice groups, each having three adjacent lattices, injecting a first glass paste containing a first color conversion material and a glass powder into a first lattice of each of the plurality of lattice groups, and injecting a second glass paste containing a second color conversion material and a glass powder into a second lattice of each of the plurality of lattice groups; sintering the first glass paste and the second glass paste; separating the partition wall structure from the substrate; and bonding a light blocking film configured to block light of a predetermined wavelength on the lattices of the partition wall structure into which the first glass paste and the second glass paste are accommodated.

According to one embodiment of the present invention, the injecting of the first glass paste and the second glass paste may include injecting a third glass paste containing a glass powder into a third lattice of each of the plurality of lattice groups; and the sintering the first glass paste and the second glass paste may include sintering the third glass paste.

According to one embodiment of the present invention, the reflective material contained in the glass paste for a partition wall, which contains the reflective material and the glass powder, may further include TiO2.

According to one embodiment of the present invention, the glass powder contained in each of the first glass paste and the second glass paste may be sintered at a temperature of 300° C. or less.

According to one embodiment of the present invention, each of the first color conversion material contained in the first glass paste and the second color conversion material contained in the second glass paste may include a quantum dot.

According to one embodiment of the present invention, the first color conversion material contained in the first glass paste may include a red fluorescent material, and the second color conversion material contained in the second glass paste may include a green fluorescent material. Further, the light blocking film, which is a blue cut filter film, may be bonded on the lattice of the partition wall structure.

According to one embodiment of the present invention, in the applying of the glass paste for a partition wall, which contains the reflective material and the glass powder, onto the substrate in the form of the lattice, an area in which the glass paste for a partition wall is applied may be formed to be larger, by as much as 15% to 20%, than a predetermined area of the partition wall structure.

According to one embodiment of the present invention, the separating of the partition wall structure from the substrate may employ any one among a laser lift off method, a chemical lift off method, a chemical mechanical polishing method, and a mechanical polishing method.

According to one embodiment of the present invention, the method may further include, after the sintering of the first glass paste and the second glass paste, planarizing one surfaces of the partition wall structure, the first glass, and the second glass.

In accordance with the embodiments of the present invention, a color conversion structure, which can be seated on a single color light-emitting diode substrate, is provided such that an assembly time of an LED chip can be reduced and thus a process time of a micro LED display can be reduced.

Further, a fluorescent material for color conversion of light emitted from the LED chip is mixed with a glass powder and sintered to form a color conversion element such that degradation in characteristic of the fluorescent material due to heat and moisture can be prevented and thus light emission efficiency can be improved.

### BRIEF DESCRIPTION OF THE DRAWINGS

FIG. 1 is a plan view of a color conversion structure for a micro light-emitting diode (LED) display according to one embodiment of the present invention.

FIG. 2 is a cross-sectional view of the color conversion structure for a micro LED display according to one embodiment of the present invention.

FIG. 3 is a diagram illustrating an emission color of an LED chip array before and after the color conversion structure for a micro LED display according to one embodiment of the present invention is applied.

FIG. 4 is a plan view of a color conversion structure for a micro LED display according to a modified example of one embodiment of the present invention.

FIG. 5 is a flowchart illustrating a manufacturing process of a color conversion structure for a micro LED display according to one embodiment of the present invention.

FIG. 6A is a diagram sequentially illustrating the manufacturing process of a color conversion structure for a micro LED display according to one embodiment of the present invention.

FIG. 6B is a diagram sequentially illustrating the manufacturing process of a color conversion structure for a micro LED display according to one embodiment of the present invention

FIG. 6C is a diagram sequentially illustrating the manufacturing process of a color conversion structure for a micro LED display according to one embodiment of the present invention

FIG. 6D is a diagram sequentially illustrating the manufacturing process of a color conversion structure for a micro LED display according to one embodiment of the present invention

### DETAILED DESCRIPTION

Hereinafter, exemplary embodiments of the present invention will be fully described in a detail which is easily practiced by those skilled in the art to which the present invention pertains with reference to the accompanying drawings. In order to clearly describe the present invention, a portion not related to the present invention will be omitted, and throughout this disclosure, like reference numerals will be assigned to like components.

In this disclosure, when one component is described as being “above” another component, this includes not only a case in which the one component is located “directly above” the another component, but also a case in which still another component is present between the one component and the another component. Further, a size and the like of each component shown in the drawings are arbitrarily illustrated for convenience of description, and thus the present invention is not necessarily limited to those shown in the drawings.

That is, it should be noted that specific shapes, structures, and features described herein can be changed and implemented from one embodiment to another embodiment without departing from the spirit and scope of the present invention, and a position or an arrangement of each component can also be changed without departing from the spirit and scope of the present invention. Accordingly, the following detailed description is not to be taken in a limiting sense, and the scope of the present invention should be construed to include the scope of the appended claims and equivalents thereof.

### Color Conversion Structure for a Micro Light-Emitting Diode (LED) Display

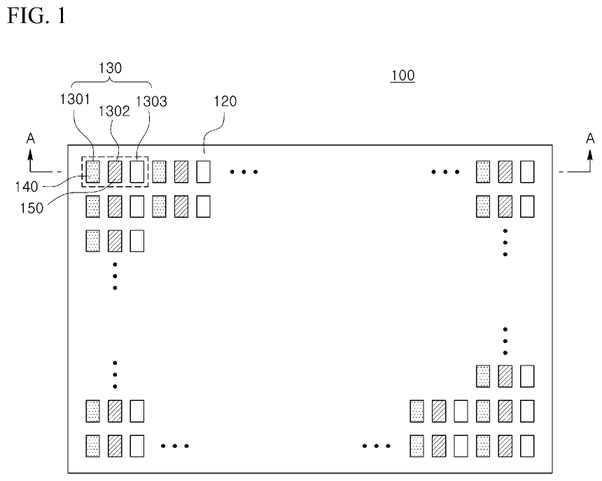

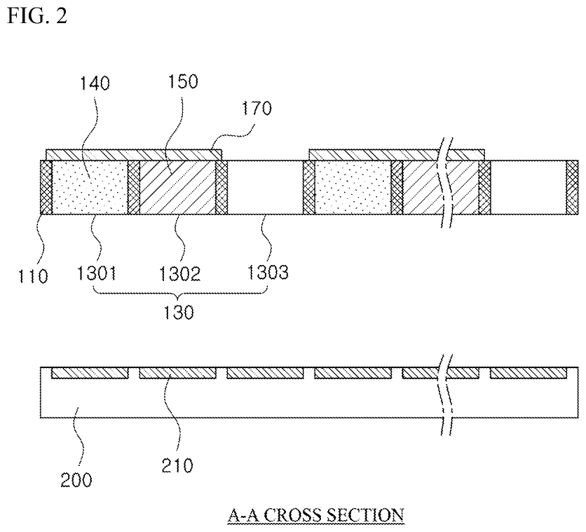

FIGS. 1 and 2 are a plan view and a cross-sectional view illustrating a color conversion structure for a micro LED display according to one embodiment of the present invention.

Referring to FIGS. 1 and 2, a color conversion structure 100 for a micro LED display according to one embodiment of the present invention includes a partition wall structure 120, and a plurality of lattices are formed in the partition wall structure 120. According to the present embodiment, the partition wall structure 120 is comprised of partition walls 110 formed in a longitudinal direction and a transverse direction, and the plurality of lattices are formed due to intersection of the partition walls 110.

The partition walls 110 of the partition wall structure 120 may be made of glass containing a reflective material. Here, the reflective material may be a high reflective or high refractive material such as TiO₂, Y₂O₃, Ta₂O₅, Al₂O₃, Bi₂O₃, Nb₂O₅, SiO₂, or the like.

According to one embodiment of the present invention, the plurality of lattices formed in the partition wall structure 120 may be divided into a plurality of lattice groups 130 in which three adjacent lattices 1301, 1302, and 1303 are set as one group. When the micro LED color conversion structure 100 is disposed on a micro LED substrate 200, each of the lattice groups 130 is disposed on three micro LED chips 210 such that light emitted from the three micro LED chips passes through each of the lattice groups 130 to exhibit red, green, and blue colors.

To this end, a color conversion material may be contained in lattices of each of the lattice groups 130. Specifically, in the present embodiment, one lattice group 130 includes a first lattice 1301, a second lattice 1302, and a third lattice 1303. A first glass 140 and a second glass 150 containing the color conversion material are accommodated in the first lattice 1301 and the second lattice 1302 among the first lattice 1301, the second lattice 1302, and the third lattice 1303, and the third lattice 1303 is formed as an empty space in which any material is not accommodated. Consequently, when the color conversion structure 100 is disposed on the single color LED chip 210, lights passing through the first lattice 1301 and the second lattice 1302 undergo a color conversion, and light passing through the third lattice 1303 is emitted without a color conversion such that different colors may be exhibited.

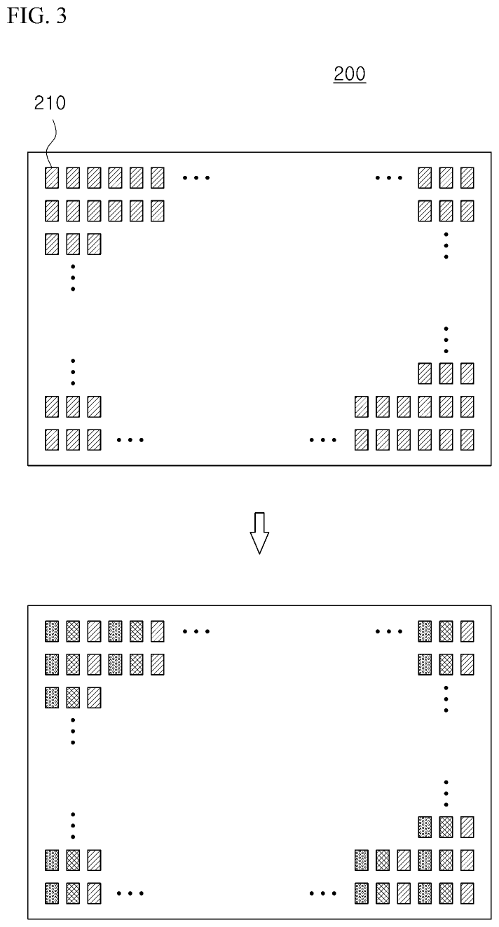

FIG. 3 is a diagram illustrating an emission color of a micro LED chip array before and after the color conversion structure for a micro LED display according to one embodiment of the present invention is applied. Referring to FIG. 3, when only a single blue color LED chip 210 is disposed on the micro LED substrate 200, the first glass 140 and the second glass 150, which contain color conversion materials capable of converting blue light into red light and green light, are accommodated in the first lattice 1301 and the second lattice 1302 so that lights passing through the first to third lattices 1301, 1302, and 1303 of one lattice group may be exhibited as red, green, and blue colors.

According to one embodiment of the present invention, the color conversion materials contained in the first glass 140 and the second glass 150 accommodated in the lattices may be quantum dots. In the case of the micro LED, since a size of the LED chip is small in a range of 100 μm or less, and in some cases, in a range of 30 μm to 50 μm, there is a limitation on application of a color conversion element such as YAG, LuAG, α-SiAlON, β-SiAlON, CaSiN, KSF, or the like having a central particle diameter ranging from 10 μm to 30 μm to the micro LED. Therefore, it is necessary to apply a color conversion element such as a quantum dot of which a center particle diameter has a nano size to the micro LED. Since the quantum dot may emit different color of light according to a particle size of the quantum dot, quantum dots having different particle sizes are used in the first lattice 1301 and the second lattice 1302 such that lights can be converted into colors of different wavelengths. For example, when only the single blue color LED chip 210 is disposed on the micro LED substrate 200, in order to implement an RGB display, the first glass 140 contains a quantum dot having a particle size of about 6 nm, and the second glass 150 contains a quantum dot having a particle size of about 3 nm such that blue light emitted from the LED chip 210 may be converted into red light and green light.

In the case of a quantum dot emitting blue light, since a particle size of the quantum dot is very small, of about 2 nm, it is relatively difficult to manufacture the quantum dot than quantum dots emitting green light and red light. Therefore, in the present embodiment, the blue color LED chip 210 is used as the LED chip, and quantum dots emitting red light and green light, which are relatively easy to be manufactured, are used as the color conversion materials such that an overall process time and manufacturing costs may be reduced.

Meanwhile, the quantum dot has excellent color reproducibility, but the particle thereof may be decomposed due to moisture, and quantum efficiency of the particle may be rapidly degraded at a predetermined temperature or above. Thus, in the present invention, the quantum dot is contained in glass so as to protect the quantum dot from heat and moisture. A detailed description of the manufacturing method will be described below.

In the present embodiment, the quantum dot is used as the color conversion material, but the present invention is not limited thereto. As described above, another known color conversion elements of which central particle diameters have a nano size may also be used.

Further, in the present embodiment, although the color conversion materials have been illustrated as being accommodated only in the first lattice 1301 and the second lattice 1302, a color conversion material may also be accommodated in the third lattice 1303 so as to implement RGB pixels according to a color of light emitted from the micro LED chip.

Referring back to FIG. 2 again, the color conversion structure 100 for a micro LED display according to one embodiment of the present invention further includes a light blocking film 170. The light blocking film 170 is disposed on the first lattice 1301 and the second lattice 1302, in which the color conversion materials are accommodated, to block light not undergoing a color conversion while the light emitted from the micro LED chip 210 passes through the color conversion materials accommodated in the first lattice 1301 and the second lattice 1302, thereby improving color purity.

In the present embodiment, a blue cut filter film may be used as the light blocking film 170 to block the blue light emitted from the micro LED chip 210 and not undergoing the color conversion while passing through the first lattice 1301 and the second lattice 1302. However, a type and an arrangement of the light blocking film 170 may be changed according to the color and the arrangement of the used micro LED chip 210.

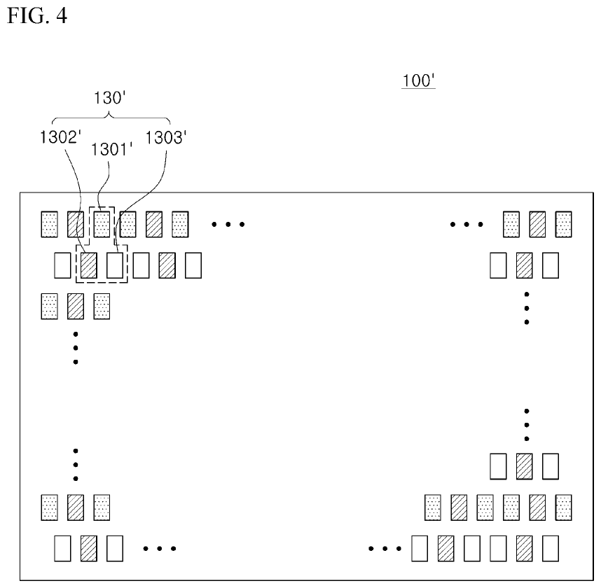

In one embodiment of the present invention, as shown in FIG. 1, the first lattice 1301, the second lattice 1302, and the third lattice 1303, which constitute one lattice group, are arranged in a line. However, a method of arranging lattices constituting one lattice group may be changed in various methods. For example, FIG. 4 is a plan view of a color conversion structure for a micro LED display according to a modified example of one embodiment of the present invention. Referring to FIG. 4, a first lattice 1301′, a second lattice 1302′, and a third lattice 1303′ may be arranged in a triangular shape in one lattice group 130′, and lattices may be arranged in an inverted triangular shape in an adjacent lattice group.

The present invention is also characterized in a method for manufacturing a color conversion structure for the above-described micro LED display. Hereinafter, the method of manufacturing a color conversion structure for a micro LED display according to one embodiment of the present invention will be described in detail.

### Method of Manufacturing a Color Conversion Structure for an LED Display

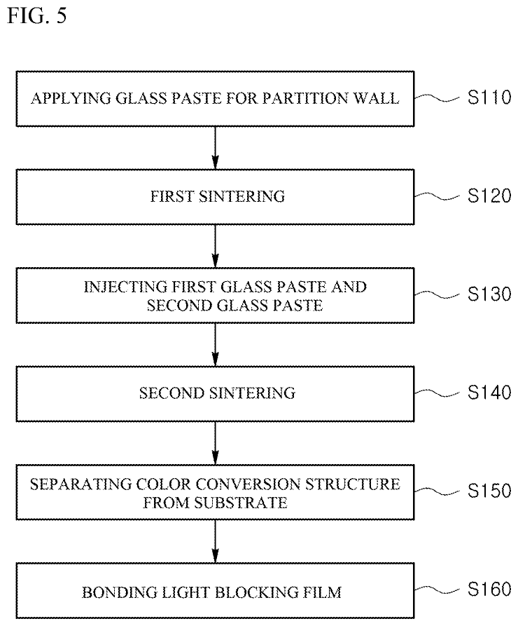

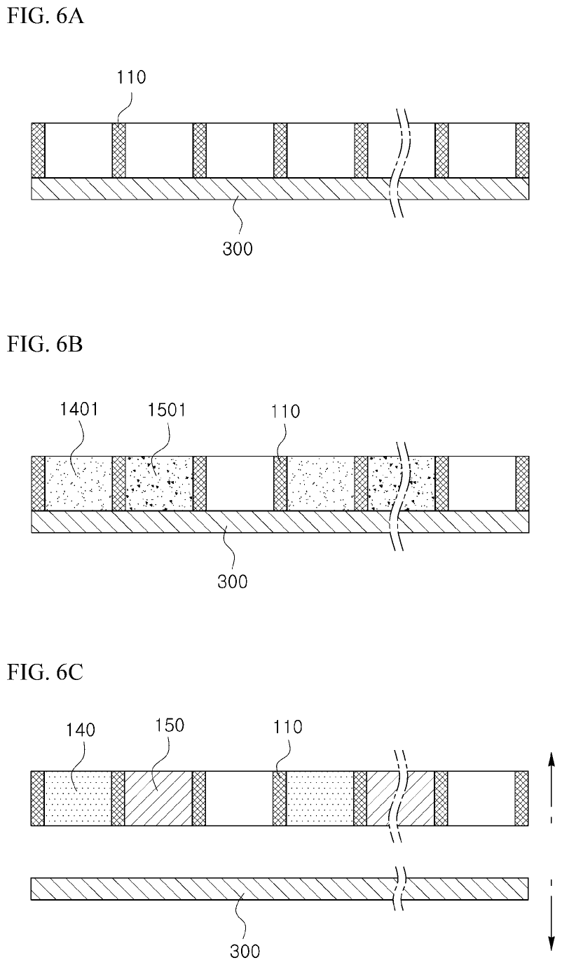

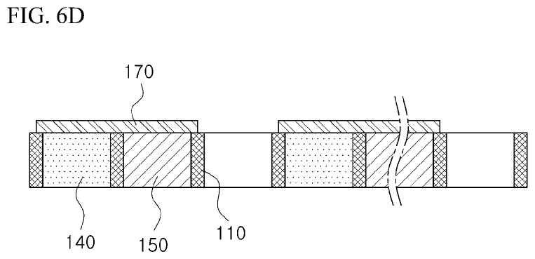

FIG. 5 is a flowchart illustrating a manufacturing process of a color conversion structure according to one embodiment of the present invention, and FIG. 6 is a diagram sequentially illustrating the manufacturing process of a color conversion structure according to one embodiment of the present invention.

In order to manufacture the color conversion structure 100 for a micro LED display according to one embodiment of the present invention, as shown in FIG. 6A, a substrate 300 is prepared first and a glass paste 1101 for a partition wall is applied onto the substrate 300 (S110). In the present embodiment, the glass paste 1101 for a partition wall is applied in a lattice form in the transverse direction and the longitudinal direction.

The substrate 300 may be made of glass, sapphire, or the like, and the glass paste 1101 for a partition wall applied onto the substrate 300 may contain a glass powder and a reflective material. The glass powder serves as a base material in forming the partition wall 110. The glass powder may contain an aluminoborosilicate glass component having SiO₂, Al₂O₃, alkaline earth metal oxides (MgO, CrO, SrO, and BaO), or B₂O₃ as a main component and may be comprised of a known glass component in addition to the above component. Further, the reflective material contained in the glass paste 1101 for a partition wall is a white pigment. The reflective material may be TiO₂ having high refractive index, an accurate particle size, dispersibility.

The glass paste 1101 for a partition wall may further contain a binder resin and a solvent. The binder resin may be added to provide a bonding force between the glass powders, and a known resin such as a polyvinyl butyral (PVB)-based resin, a polyvinyl alcohol (PVA)-based resin, an acrylic-based resin, a cellulose-based resin, or the like may be used as the binder resin. The solvent serves to control viscosity of the glass paste. The solvent is volatilized and removed during a drying process, and an alcohol solvent, a ketone solvent, or the like may be used alone or in combination of two or more thereof as the solvent.

Next, first sintering is performed to sinter the glass paste 1101 for a partition wall applied onto the substrate 300 in a lattice form (S120). The first sintering may be performed at a temperature of 300° C. or more. Preferably, the first sintering may be performed at a temperature of 600° C. or more so as to make the partition wall structure 120 have sufficient mechanical strength and secure compactness of sintering in the first sintering. Consequently, the partition wall structure 120 of the color conversion structure for a micro LED display according to the present embodiment is formed.

As described above, the partition wall structure 120 according to the present embodiment is formed by containing the reflective material TiO₂ such that a process of applying the reflective material may be omitted after the partition wall is formed, thereby achieving an effect of reducing a process time and manufacturing costs of the color conversion structure of the micro LED display.

Meanwhile, while the glass paste 1101 for a partition wall applied onto the substrate 300 is sintered, shrinkage of the glass paste 1101 may occur as a density thereof increases. Thus, when the glass paste 1101 for a partition wall is applied onto the substrate 300, the glass paste 1101 for a partition wall is applied to a larger area than a cross-sectional area of the partition wall which will be formed. For example, an application area of the glass paste 1101 for a partition wall is formed to be larger, by as much as 15% to 20%, than a cross-sectional area of the partition wall structure 120 which will be formed.

Next, as shown in FIG. 6B, a glass paste containing the color conversion material is injected into a lattice of the partition wall structure 120 (S130). Specifically, the first glass paste 1401 containing a first color conversion material and a glass powder and the second glass paste 1501 containing a second color conversion material and a glass powder are respectively injected into two lattices (a first lattice and a second lattice) among three adjacent lattices constituting one lattice group.

The glass powders of the first glass paste and the second glass paste serve as base materials in forming the color conversion elements and are formed of materials, which are low temperature sinterable, e.g., P₂O₅—SnO₂-based materials, P₂O₅—SnO₂—SnF-based materials, or P₂O₅—ZnO—SnO-based materials, so as to prevent deformation of the color conversion elements during a sintering process. Further, like the glass paste for a partition wall, the first glass paste and the second glass paste may further include binder resins and solvents in addition to the color conversion materials and the glass powders.

The first color conversion material and the second color conversion material, which are respectively included in the first glass paste and the second glass paste, are materials which convert light emitted from the LED chip into different color lights. In the present embodiment, quantum dots are used as the first color conversion material and the second color conversion material. Specifically, as described above, quantum dots having different particle sizes are used as the first color conversion material and the second color conversion material so that light emitted from the blue LED chip is converted into red color light and green color light.

After the glass pastes 1401 and 1501 are injected into the lattices, second sintering which is a process of sintering the injected glass pastes 1401 and 1501 is performed (S140).

In the present embodiment, the second sintering is performed at a temperature ranging from 120° C. to 300° C. When the sintering temperature is lower than 120° C., since the sintering temperature is lower than a softening behavior temperature and thus the sintering is not performed properly, a large amount of bubbles are generated in the glass such that light transmittance may be degraded. When the sintering temperature is higher than 300° C., the color conversion material included in the glass paste is denatured to not perform a desired color conversion function. In particular, as described above, the quantum dot used as the color conversion material in the present embodiment is very vulnerable to heat. Thus, in the present embodiment, the second sintering is performed at a temperature of less than 300° C., more preferably, less than 250° C. so as to prevent denaturation of the quantum dot.

After the second sintering, exposed one surfaces of the partition wall 110, the first glass 140, and the second glass 150, which are sintered, may be planarized. While the glass paste 1101 for a partition wall and the glass pastes 1401 and 1501 are sintered, the exposed surfaces may be irregularly formed due to reaction and shrinkage between the materials included in the glass pastes. When the light emitted from the LED chip penetrates the irregular surfaces, scattering occurs such that color reproducibility may be degraded. Therefore, in the present embodiment, after the second sintering, a process of planarizing one surfaces of the partition wall 110, the first glass 140, and the second glass 150 may be performed to prevent degradation in color reproducibility. The planarization process may employ a known method such as a chemical mechanical polishing (CMP) process or the like.

Subsequently, as shown in FIG. 6C, the partition wall structure 120 is separated from the substrate 300 (S150). In the present embodiment, a laser lift off method is used to separate the partition wall structure 120 from the substrate 300, but the present invention is not limited thereto, and a chemical lift off (CLO) method, a CMP method, or a mechanical polishing (MP) method may be applied, and the partition wall structure 120 may be separated by other known method in addition to the above-described method.

Finally, as shown in FIG. 6D, the light blocking film is bonded on the lattice accommodating the color conversion material (S160). As described above, in the present embodiment, the first color conversion material and the second color conversion material for converting to red color light and green color light are respectively accommodated in the first lattice and the second lattice in each lattice group. Consequently, the light emitted from the blue color LED chip is converted into red color light and green color light to implement RGB pixels. Accordingly, in the present embodiment, the blue cut filter film serving as the light blocking film 170 is bonded to the first lattice and the second lattice to block the blue light not undergoing the color conversion while passing through the first lattice and the second lattice such that color purity may be improved.

As described above, according to the color conversion structure for a micro LED display and the method of manufacturing the same according to one embodiment of the present invention, since an RGB display may be implemented using an LED substrate comprised of a single color LED chip, a time required for assembling the LED chip on the LED substrate during the manufacturing process of the micro LED display may be significantly reduced. Further, in order for a color conversion of the light emitted from the LED chip, the glass paste containing the color conversion material such as the quantum dot is injected into a structure and sintered to form the color conversion structure such that the color conversion material may be protected from heat and moisture and characteristic degradation of the color conversion material due to the heat and the moisture may be prevented. Further, the blue cut filter film is bonded on the lattice to block a small amount of blue light not undergoing the color conversion such that color reproducibility and color purity of the micro LED display may be increased.

While the exemplary embodiments of the present invention have been described with reference to the accompanying drawings, those skilled in the art to which the present invention pertains can understand that the present invention can be implemented in other specific forms without departing from the technical spirit or the necessary features of the present invention.

What is claimed is:

1. A method of manufacturing a color conversion structure for a micro light-emitting diode (LED) display, the method comprising:
applying a glass paste for a partition wall, which contains a reflective material and a glass powder, onto a substrate in a form of a lattice;
sintering the glass paste for a partition wall to form a partition wall structure;
dividing the lattice in the partition wall structure into a plurality of lattice groups, each having three adjacent lattices, injecting a first glass paste containing a first color conversion material and a glass powder into a first lattice of each of the plurality of lattice groups, and injecting a second glass paste containing a second color conversion material and a glass powder into a second lattice of each of the plurality of lattice groups;
sintering the first glass paste and the second glass paste;
separating the partition wall structure from the substrate; and
bonding a light blocking film configured to block light of a predetermined wavelength on the lattices of the partition wall structure into which the first glass paste and the second glass paste are injected.

2. The method of claim 1, wherein:
the injecting of the first glass paste and the second glass paste includes injecting a third glass paste containing a glass powder into a third lattice of each of the plurality of lattice groups; and
the sintering the first glass paste and the second glass paste includes sintering the third glass paste.

3. The method of claim 1, wherein the reflective material contained in the glass paste for a partition wall, which contains the reflective material and the glass powder, includes TiO₂.

4. The method of claim 1, wherein the glass powder contained in each of the first glass paste and the second glass paste has a sintering temperature of 300° C. or less.

5. The method of claim 1, wherein each of the first color conversion material contained in the first glass paste and the second color conversion material contained in the second glass paste includes a quantum dot.

6. The method of claim 1, wherein the first color conversion material contained in the first glass paste includes a red fluorescent material, and the second color conversion material contained in the second glass paste includes a green fluorescent material.

7. The method of claim 6, wherein the light blocking film bonded on the lattice of the partition wall structure includes a blue cut filter film.

8. The method of claim 1, wherein, in the applying of the glass paste for a partition wall, which contains the reflective material and the glass powder, onto the substrate in the form of the lattice, an area in which the glass paste for a partition wall is applied is formed to be larger, by as much as 15% to 20%, than a predetermined area of the partition wall structure.

9. The method of claim 1, wherein the separating of the partition wall structure from the substrate employs any one among a laser lift off method, a chemical lift off method, a chemical mechanical polishing method, and a mechanical polishing method.

10. The method of claim 1, further comprising:
after the sintering of the first glass paste and the second glass paste, planarizing one surfaces of the partition wall structure, a first glass formed by the first glass paste, and a second glass formed by the second glass paste.
